(19) United States
(12) Patent Application Publication
(10) Pub. No.: US 2026/0156826 A1
(43) Pub. Date: Jun. 4, 2026

(54) SEMICONDUCTOR DEVICE AND ELECTRONIC SYSTEM INCLUDING THE SAME

(71) Applicant: Samsung Electronics Co., Ltd., Suwon-si (KR)

(72) Inventors: Gyeongsik EOM, Suwon-si (KR); Kang Lib KIM, Suwon-si (KR); Jemin AHN, Suwon-si (KR); Yunjo LEE, Suwon-si (KR); Jaehoon LEE, Suwon-si (KR); Dongjin LEE, Suwon-si (KR); Jaeduk LEE, Suwon-si (KR)

(73) Assignee: Samsung Electronics Co., Ltd., Suwon-si (KR)

(21) Appl. No.: 19/190,969

(22) Filed: Apr. 28, 2025

(30) Foreign Application Priority Data
Dec. 2, 2024 (KR) 10-2024-0176485

(51) Int. Cl. H10B 43/40; H01L 25/065; H01L 25/18; H10B 43/27; H10B 80/00

(52) U.S. Cl. CPC H10B 43/40; H10B 43/27; H10B 80/00; H10W 90/00; H10W 42/271

(57) ABSTRACT

A semiconductor device including, lower peripheral circuit structure including a lower peripheral circuit substrate, a plurality of lower peripheral circuit elements on the lower peripheral circuit substrate, a lower peripheral insulating film stacked on the lower peripheral circuit substrate, and a lower peripheral wiring structure in the lower peripheral insulating film; upper peripheral circuit structure stacked on the lower peripheral circuit structure along a first direction and including an upper peripheral circuit substrate, a plurality of upper peripheral circuit elements on the upper peripheral circuit substrate, an upper peripheral insulating film staked on the upper peripheral circuit substrate, and an upper peripheral wiring structure arranged in the upper peripheral insulating film; and bonding structure including a shielding element, and being between the lower and upper peripheral circuit structures, the shielding element overlapping a first upper peripheral circuit element of the plurality of upper peripheral circuit elements in the first direction.

### CROSS-REFERENCE TO RELATED APPLICATION

This application claims priority to Korean Patent Application No. 10-2024-0176485, filed in the Korean Intellectual Property Office on Dec. 2, 2024, the entire contents of which are hereby incorporated by reference in its entirety.

### BACKGROUND

### Field

Some example embodiments relate to a semiconductor device and an electronic system including the same.

### Description of Related Art

Semiconductor devices capable of storing high-capacity data are in high demand for electronic systems that require and/or perform data storage. Accordingly, methods for increasing the data storage capacity of semiconductor devices have been studied. For example, as a method for increasing the data storage capacity of semiconductor devices, semiconductor devices including three-dimensionally arranged memory cells have been proposed rather than semiconductor devices including two-dimensionally arranged memory cells.

### SUMMARY

Some example embodiments provide a semiconductor device with the advanced electrical characteristic and reliability.

Some example embodiments provide an electronic system with the advanced and/or enhanced electrical characteristic and reliability.

According to some example embodiments, there is provided a semiconductor device including a lower peripheral circuit structure including a lower peripheral circuit substrate, a plurality of lower peripheral circuit elements on the lower peripheral circuit substrate, a lower peripheral insulating film stacked on the lower peripheral circuit substrate, and a lower peripheral wiring structure in the lower peripheral insulating film; an upper peripheral circuit structure stacked on the lower peripheral circuit structure in a first direction, the upper peripheral circuit structure including an upper peripheral circuit substrate, a plurality of upper peripheral circuit elements disposed on the upper peripheral circuit substrate, an upper peripheral insulating film staked on the upper peripheral circuit substrate, and an upper peripheral wiring structure arranged in the upper peripheral insulating film; and a bonding structure including a shielding element, the bonding structure being between the lower peripheral circuit structure and the upper peripheral circuit structure, the shielding element overlapping a first upper peripheral circuit element of the plurality of upper peripheral circuit elements in the first direction.

According to some example embodiments, there is provided a semiconductor device including a lower peripheral circuit structure including a lower peripheral circuit substrate, a plurality of lower peripheral circuit elements on the lower peripheral circuit substrate, a lower peripheral insulating film on the lower peripheral circuit substrate, and a lower peripheral wiring structure in the lower peripheral insulting film; an upper peripheral circuit structure stacked on the lower peripheral circuit structure in a first direction, the upper peripheral circuit structure including an upper peripheral circuit substrate, a plurality of upper peripheral circuit elements on the upper peripheral circuit substrate, an upper peripheral insulating film stacked on the upper peripheral circuit substrate, and an upper peripheral wiring structure in the upper peripheral insulting film; a bonding structure including a shielding element, the bonding structure being between the lower peripheral circuit structure and the upper peripheral circuit structure; and a cell structure stacked on the lower peripheral circuit structure or the upper peripheral circuit structure in the first direction, the cell structure including a cell substrate including a cell array region and an extension region; a mold structure including a plurality of mold insulating layers and a plurality of gate electrodes alternately stacked on the cell substrate in the first direction; a channel structure on the cell array region, penetrating the mold structure, and extending in the first direction; and a word line contact on the extension region, penetrating a portion of the mold structure, and extending in the first direction, and the shielding element overlapping a first upper peripheral circuit element of the plurality of upper peripheral circuit elements in the first direction.

According to some example embodiments, there is provided a an electronic system including a main substrate; a semiconductor device stacked on the main substrate; and a controller electrically connected to the semiconductor device on the main substrate, the semiconductor device including a lower peripheral circuit structure including a lower peripheral circuit substrate, a plurality of lower peripheral circuit elements on the lower peripheral circuit substrate, a lower peripheral insulating film stacked on the lower peripheral circuit substrate, and a lower peripheral wiring structure in the lower peripheral insulating film; an upper peripheral circuit structure stacked on the lower peripheral circuit structure in a first direction, and the upper peripheral circuit structure including an upper peripheral circuit substrate, a plurality of upper peripheral circuit elements on the upper peripheral circuit substrate, an upper peripheral insulating film stacked on the upper peripheral circuit substrate, and the upper peripheral wiring structure in the upper peripheral insulating film; a bonding structure including a shielding element, the bonding structure being between the lower peripheral circuit structure and the upper peripheral circuit structure, the shielding element overlapping a first upper peripheral circuit element of the plurality of upper peripheral circuit elements in the first direction; and a cell structure, the cell structure including a cell substrate including, a cell array region and an extension region; a mold structure including a plurality of mold insulating layers and a plurality of gate electrodes alternately stacked on the cell substrate in the first direction; a channel structure on the cell array region, penetrating the mold structure, and extending in the first direction; and a word line contact on the extension region, penetrating a portion of the mold structure, and extending in the first direction.

According to some example embodiments, there is provided a method of manufacturing a semiconductor device, the method including forming a lower peripheral circuit structure, the lower peripheral circuit structure formed by forming a lower peripheral circuit substrate, forming a plurality of lower peripheral circuit elements on the lower peripheral circuit substrate, stacking a lower peripheral insulating film on the lower peripheral circuit substrate, and forming a lower peripheral wiring structure in the lower peripheral insulating film; forming an upper peripheral circuit structure stacked on the lower peripheral circuit structure in a first direction, the upper peripheral circuit structure formed by forming an upper peripheral circuit substrate, forming a plurality of upper peripheral circuit elements on the upper peripheral circuit substrate, stacking an upper peripheral insulating film on the upper peripheral circuit substrate, and forming an upper peripheral wiring structure in the upper peripheral insulating film; and forming a boding structure between the lower peripheral circuit structure and the upper peripheral circuit structure, the bonding structure including a shielding element formed in the bonding structure, the shielding element overlapping a first upper peripheral circuit element of the plurality of upper peripheral circuit elements in the first direction.

In some example embodiments, the bonding structure is formed by forming a lower bonding layer on the lower peripheral circuit structure, forming a lower pad inside the lower bonding layer, forming an upper bonding layer on the upper peripheral circuit structure, and forming an upper pad inside the upper bonding layer corresponding to the lower pad.

In some example embodiments, the shielding element is formed within the upper bonding layer.

In some example embodiments, the method further comprises performing a planarization process on the upper peripheral circuit substrate prior to the upper bonding layer being formed.

In some example embodiments, a thickness of the upper peripheral circuit substrate after the upper bonding layer is formed is smaller than a thickness of the upper peripheral circuit substrate prior to the upper bonding layer being formed.

According to some example embodiments, a shielding element is placed inside a bonding structure between an upper peripheral circuit structure and a lower peripheral circuit structure overlapping each other in a vertical direction. Accordingly, a shielding member may block and/or mitigate the influence of the voltage applied to a wiring line of the lower peripheral circuit structure, thereby maintaining the characteristic of an upper peripheral circuit element.

### BRIEF DESCRIPTION OF DRAWINGS

FIG. 1 is a plan view illustrated to explain a semiconductor device according to some example embodiments;

FIG. 2 is a cross-sectional view of FIG. 1 taken along line A-A according to some example embodiments;

FIG. 3 to FIG. 8 are views illustrated to explain examples of shielding elements according to some example embodiments;

FIG. 9 and FIG. 10 are views illustrated to explain examples of shielding elements according to some example embodiments;

FIG. 11 to FIG. 13 are views illustrated to explain examples of shielding elements according to some example embodiments;

FIG. 14 is a view illustrated to explain a semiconductor device according to some example embodiments;

FIG. 15 is a view illustrated to explain a semiconductor device according to some example embodiments;

FIG. 16 is a view illustrated to explain a semiconductor device according to some example embodiments;

FIG. 17 to FIG. 21 are views illustrated to explain a manufacturing method of a semiconductor device according to some example embodiments;

FIG. 22 is an exemplary block view illustrated to explain an electronic system according to some example embodiments;

FIG. 23 is an exemplary perspective view illustrated to explain an electronic system including a semiconductor device according to some example embodiments; and

FIG. 24 is a schematic cross-sectional view of FIG. 23 taken along line V-V according to some example embodiments.

### DETAILED DESCRIPTION

Some example embodiments of the present inventive concepts will be described in detail with reference to the attached drawings.

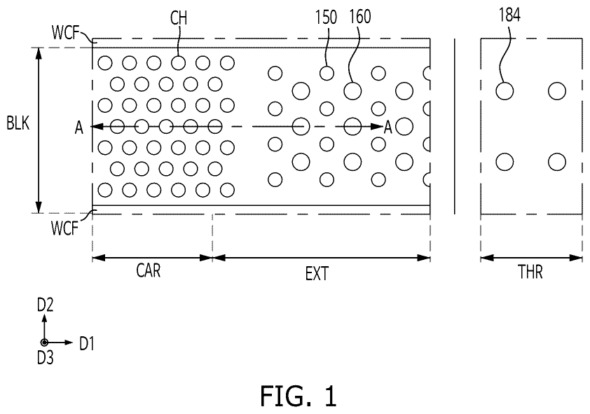

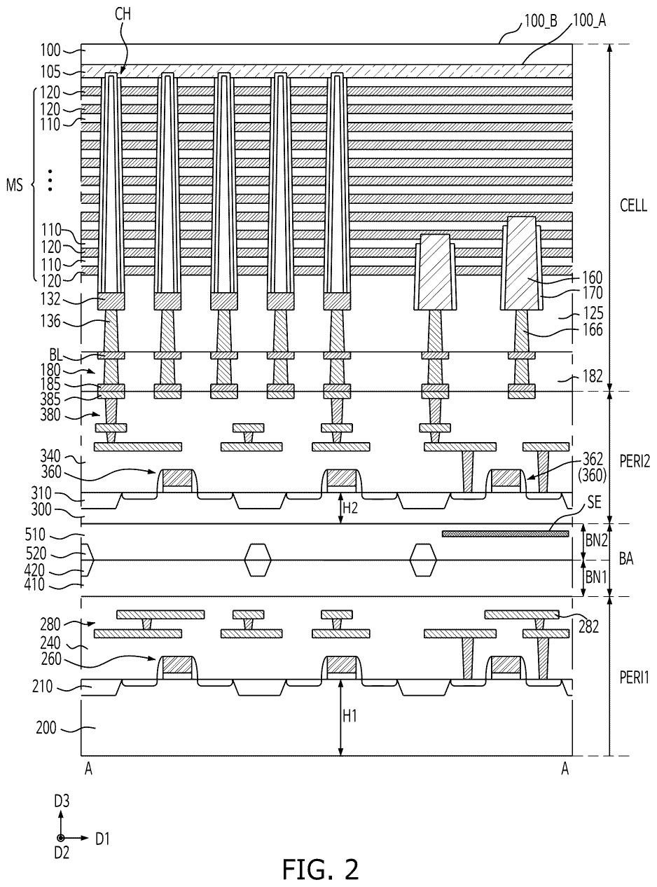

FIG. 1 is a plan view illustrated to explain a semiconductor device according to some example embodiments. FIG. 2 is a cross-sectional view of FIG. 1 taken along line A-A according to some example embodiments.

A semiconductor device according to some example embodiments may be a chip-to-chip (C2C) structure in which a plurality of peripheral circuit structures PERI1 and PERI2 are connected to a cell structure CELL. For example, a semiconductor device may include a structure in which a first chip including a lower peripheral circuit structure PERI1 on a first wafer (e.g., 200 of FIG. 2), a second chip including an upper peripheral circuit structure PERI2 on a second wafer (e.g., 300 of FIG. 2), and a third chip including a cell structure CELL on a third wafer (e.g., 100 of FIG. 2) are connected by bonding. According to some example embodiments, upper and lower portions, and upper and lower surfaces are only for ease of explanation, but the example embodiments are not limited thereto. According to some example embodiments, the upper and lower portions, and upper and lower surfaces are indicated based on what are in the drawing, and the terms for the upper and lower relationship may be changed when the drawing is rotated up and down. As described herein, it will be understood that when an element such as a layer, film, region, or substrate is referred to as being “on” another element, it may be directly on the other element or intervening elements may also be present. In contrast, when an element is referred to as being “directly on” another element, there are not intervening elements present. It will further be understood that when an element is referred to as being “on” another element, it may be above or beneath or adjacent (e.g., horizontally adjacent) to the other element.

Referring to FIG. 1 and FIG. 2, a semiconductor device according to some example embodiments may include a lower peripheral circuit structure PERI1, an upper peripheral circuit structure PERI2, and a cell structure CELL.

The cell structure CELL may include a cell substrate 100, a common source plate 105, a mold structure MS, a channel structure CH, a bit line BL, a word line contact 160, a contact spacer 170, a cell wiring structure 180, etc.

The cell substrate 100 may include a cell array region CAR, an extension region EXT, and a through region THR.

A memory cell array including a plurality of memory cells may be formed on the cell array region CAR. The channel structure CH, the mold structure MS, the bit line BL, etc. may be arranged on the cell array region CAR. According to some example embodiments, the expression that configuration B is formed and/or arranged on configuration A is not limited that configuration is formed and/or arranged in contact with configuration A. For example, the present inventive concepts may include some example embodiments where configuration C is disposed between configuration B and configuration A. In some example embodiments, the expression that configuration B is formed and/or arranged on configuration A is not limited that configuration B is arranged on the upper side of configuration A. For example, the present inventive concepts may include some example embodiments where configuration B is arranged on the lower, right, or left side of configuration A.

The extension region EXT may be arranged at the periphery of the cell array region CAR. For example, the extension region EXT may surround the cell array region CAR. A word line contact 160, a contact spacer 170, a dummy channel structure 150, etc. may be arranged on the extension region EXT.

The through region THR may be arranged at the outer side of the extension region EXT. For example, the through region THR may be arranged on one side of the extension region EXT, but example embodiments are not limited thereto. A source contact 184, an input and output contact, etc. may be placed on the through region THR.

The cell substrate 100 may include a semiconductor substrate such as a silicon substrate, a germanium substrate, or a silicon-germanium substrate. Alternatively, the cell substrate 100 may include a silicon-on-insulator (SOI) substrate, a germanium-on-insulator (GOI) substrate, etc. According to some example embodiments, the cell substrate 100 may include polysilicon (poly Si).

The cell substrate 100 may include a first surface 100_A and a second surface 100_B facing the first surface 100_A. The mold structure MS and the channel structure CH may be placed on the first surface 100_A. The first surface 100_A of the cell substrate 100 may be referred to as a front side of the cell substrate 100. The second surface 100_B of the cell substrate 100 may be referred to as a back side of the cell substrate 100.

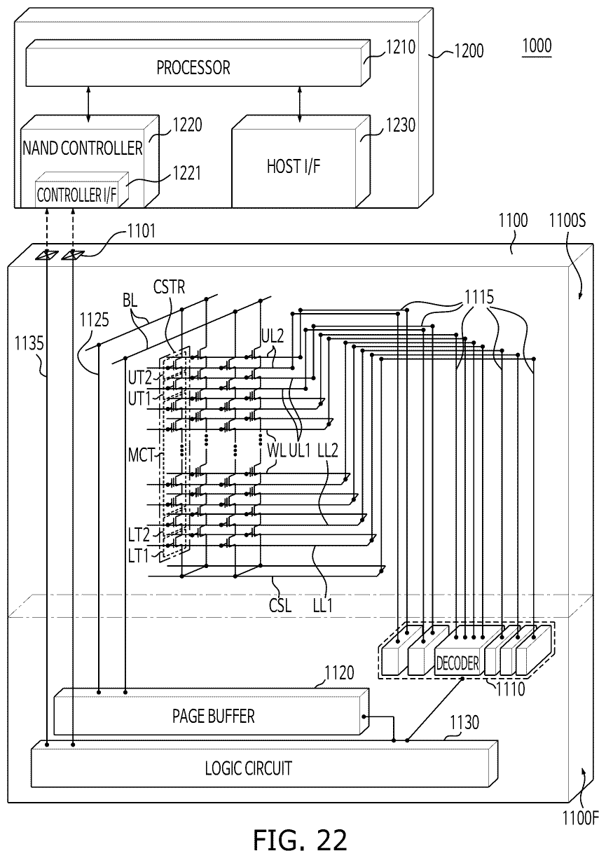

The common source plate 105 may be placed on the first surface 100_A of the cell substrate 100. The common source plate 105 may be placed on the cell array region CAR, the extension region EXT, and the through region THR. The common source plate 105 may contact the channel structure CH. For example, the common source plate 105 may be electrically connected to the channel layer of the channel structure CH. The common source plate 105 may contact the source contact 184 in the through region THR. The common source plate 105 may be provided to a common source line (e.g., CSL of FIG. 22) of the semiconductor device. The common source plate 105 may include, for example, polycrystalline silicon or metal doped with impurities, but example embodiments are not limited thereto.

The mold structure MS may be placed on the common source plate 105. The mold structure MS may be placed on the cell array region CAR and the extension region EXT of the cell substrate 100. The mold structure MS may include a plurality of mold insulating layers 110 and a plurality of gate electrodes 120 alternately stacked in a third direction D3. Each of the plurality of mold insulating layers 110 and each of the plurality of gate electrodes 120 may have a layered structure extending parallel to the first surface 100_A of the cell substrate 100. It will be understood that elements and/or properties thereof (e.g., structures, surfaces, directions, or the like), which may be referred to as being “perpendicular,” “parallel,” “coplanar,” or the like with regard to other elements and/or properties thereof (e.g., structures, surfaces, directions, or the like) may be “perpendicular,” “parallel,” “coplanar,” or the like or may be “substantially perpendicular,” “substantially parallel,” “substantially coplanar,” respectively, with regard to the other elements and/or properties thereof. The gate electrodes 120 may be spaced apart from each other by the mold insulating layers 110 and sequentially stacked on the common source plate 105.

According to some example embodiments, a portion of the plurality of gate electrodes 120 may be provided to a ground select line GSL of the semiconductor device. The other portion of the plurality of gate electrodes 120 may be provided to a string select line SSL. For example, a gate electrode 120 adjacent to the common source plate 105, among the plurality of gate electrodes 120, may be provided to the ground select line GSL. A gate electrode 120 adjacent to the bit line BL among the plurality of gate electrodes 120 may be provided to the string select line SSL. However, example embodiments are not limited thereto, and in some example embodiments the number and arrangement of the ground select lines GSL and the string select lines SSL may vary.

A mold insulating layer 110 may include an insulating material. The mold insulating layer 110 may include, for example, at least one of silicon oxide, silicon nitride, and silicon oxynitride, but the example embodiments are not limited thereto.

The gate electrode 120 may include a conductive material. The gate electrode 120 may include, for example, a metal such as tungsten (W), cobalt (Co), nickel (Ni), or a semiconductor material such as silicon, but the example embodiments are not limited thereto.

A cell interlayer insulating film 125 may be formed on the first surface 100_A of the cell substrate 100. The cell interlayer insulating film 125 may be disposed on the mold structure MS and cover the mold structure MS. The cell interlayer insulating film 125 may include at least one of, for example, silicon oxide, silicon oxynitride, and a low-k material having a lower dielectric constant than silicon oxide, but example embodiments are not limited thereto.

The channel structure CH may be disposed on the cell array region CAR of the cell substrate 100. The channel structure CH may extend in the third direction D3 perpendicular to the first surface 100_A of the cell substrate 100. The channel structure CH may penetrate the mold structure MS. For example, the channel structure CH may penetrate through and intersect with each of the plurality of the gate electrodes 120. The channel structure CH may have a pillar shape (e.g., a cylindrical shape) extending in the third direction D3. According to some example embodiments, the cross-section of the channel structure CH may have an inclined surface with a width becoming narrower toward the cell substrate 100. However, example embodiments are not limited thereto.

According to some example embodiments, the channel structure CH may include a filling insulating layer, a channel layer, and an information storage film.

The channel layer may extend in the third direction D3 and penetrate the mold structure MS. The channel layer may have various shapes such as a cylindrical shape, a square cylinder shape, a solid filler shape, etc. The channel layer may include a semiconductor material, such as single crystal silicon, polycrystalline silicon, an organic semiconductor material, and a carbon nanostructure, but example embodiments are not limited thereto.

The information storage film may be interposed between the channel layer and each gate electrode. For example, the information storage film may extend along an outer side surface of the channel layer. The information storage film may include, for example, at least one of silicon oxide, silicon nitride, silicon oxynitride, and a high-k material having a higher dielectric constant than silicon oxide. The high-k material may include, for example, at least one of aluminum oxide, hafnium oxide, lanthanum oxide, tantalum oxide, titanium oxide, lanthanum hafnium oxide, lanthanum aluminum oxide, dysprosium scandium oxide, and/or combinations thereof.

According to some example embodiments, the channel structures CH may be arranged in a zigzag shape. For example, as shown in FIG. 1, the channel structure CH may be alternately arranged in a first direction D1 and in a second direction D2. The channel structures arranged in the zigzag shape may improve the integration of semiconductor devices. According to some example embodiments, the channel structure CH may be arranged in a honeycomb shape.

According to some example embodiments, the information storage film may be formed in multiple-layers. The information storage film may include a tunnel insulating layer, a charge storage film, and a blocking insulating film sequentially stacked at the outer side surface of the channel layer.

The tunnel insulating film may include, for example, silicon oxide or a high-k material having a higher dielectric than silicon oxide (e.g., aluminum oxide (Al2O3), hafnium oxide (HfO2)). The charge storage film may include, for example, silicon nitride. The blocking insulating film may include, for example, silicon oxide or a high-k material having a higher dielectric than silicon oxide (e.g., aluminum oxide (Al2O3), hafnium oxide (HfO2)).

According to some example embodiments, the channel structure CH may further include a filling insulating layer. The filling insulating layer may be formed to fill the inside of the channel layer in a cup shape. The filling insulating layer may include an insulating material, for example, silicon oxide, but example embodiments are not limited thereto.

According to some example embodiments, a channel pad 132 may be placed on the channel structure CH. The channel pad 132 may contact a channel layer. For example, the channel pad 132 may be provided to the inside of the cell interlayer insulating film 125 to contact one end of the channel layer. The channel pad 132 may include, for example, poly silicon doped with impurities, but example embodiments are not limited thereto.

The mold structure MS may be divided by word line cut regions WCF to form a memory cell block (e.g., BLK of FIG. 1). The word line cut regions WCF may include at least one of silicon oxide, silicon nitride and silicon oxynitride, but example embodiments are not limited thereto.

The bit lines BL may be formed on the mold structure MS. The bit lines BL may intersect with the word line cut regions WCF. For example, each bit line BL may extend in the second direction D2. The bit lines BL may be spaced apart from each other and arranged in the first direction D1.

The bit lines BL may contact the channel structure CH arranged along the second direction D2. A bit line contact 136 may be formed in the cell interlayer in film 125. The bit line BL may be electrically connected to the channel structure CH through the bit line contact 136 and the channel pad 132.

The word line contact 160 may be placed on the extension region EXT of the cell substrate 100. The word line contact 160 may extend in the third direction D3 to contact the gate electrode 120. For example, the word line contact 160 may penetrate a portion of the mold structure MS and contact the corresponding gate electrode 120. FIG. 2 illustrates that the word line contact 160 penetrates one or more gate electrodes among the plurality of gate electrodes and contacts the corresponding gate electrode 120, but example embodiments are not limited thereto. According to some example embodiments, the word line contact 160 may be placed on the extension region EXT of the cell substrate 100 to contact the corresponding gate electrode 120 among a plurality of gate electrodes having a step structure.

The contact spacer 170 may be placed on the side surface of the word line contact 160. The contact spacer 170 may extend in the third direction D3 along the side surface of the word line contact 160. The contact spacer 170 may surround the word line contact 160. The contact spacer 170 may include an insulating layer. The contact spacer 170 may include, for example, an insulating material of silicon oxide series.

A word line via 166 may be placed on the word line contact 160. The word line via 166 may be placed in the cell interlayer insulating film 125. The word line contact 160 may be electrically connected to a cell wiring structure 180 through the word line via 166.

The dummy channel structure 150 may be placed on the extension region EXT of the cell substrate 100. The dummy channel structure 150 may be placed at the periphery of the word line contact 160. The dummy channel structure 150 may include an insulating material. For example, the dummy channel structure 150 may include an insulating material of oxide series, but example embodiments are not limited thereto.

The cell wiring structure 180 may be formed on the mold structure MS. For example, a cell wiring insulating film 182 may be formed on the cell interlayer insulating film 125, and the cell wiring structure 180 may be formed in the cell wiring insulating film 182. The cell wiring structure 180 may be electrically connected to the bit line BL and the word line contact 160. The cell wiring structure 180 may be electrically connected to the channel structure CH and the gate electrode 120. The number and/or the arrangement of layers of the cell wiring structure 180 is merely exemplary, and example embodiments are not limited thereto.

According to some example embodiments, the cell structure CELL and the peripheral circuit structures PERI1 and PERI2 may be stacked. For example, the upper peripheral circuit structure PERI2 may be stacked on the lower peripheral circuit structure PERI1. The cell structure CELL may be stacked on the upper peripheral circuit structure PERI2.

The lower peripheral circuit structure PERI1 may include a lower peripheral circuit substrate 200, a plurality of lower peripheral circuit elements 260 placed on the lower peripheral circuit substrate 200, a lower peripheral insulating film 240 stacked on the lower peripheral circuit substrate 200, and a lower peripheral wiring structure 280 placed in the lower peripheral insulating film 240. The lower peripheral wiring structure 280 may include a plurality of wiring layers and a connection via placed in the lower peripheral insulating film 240.

The upper peripheral circuit structure PERI2 may include an upper peripheral circuit substrate 300, a plurality of upper peripheral circuit elements 360 placed on the upper peripheral circuit substrate 300, an upper peripheral insulating film 340 stacked on the upper peripheral circuit substrate 300, and an upper peripheral wiring structure 380. The upper peripheral wiring structure 380 may include the upper peripheral wiring structure 380 placed in the upper peripheral insulating film 340. The upper peripheral wiring structure 380 may include a plurality of wiring layers and a connection via placed in the upper peripheral insulating film 340.

The lower and upper peripheral circuit substrates 200 and 300 may include a semiconductor substrate such as a silicon substrate, a germanium substrate, or a silicon-germanium substrate. Alternatively, the upper peripheral circuit substrate 300 may include a silicon-on-insulator (SOI) substrate, a germanium-on-insulator (GOI) substrate, etc.

A lower peripheral circuit element 260 may be formed on the lower peripheral circuit substrate 200. The upper peripheral circuit element 360 may be formed on the upper peripheral circuit substrate 300. Each of the lower and upper peripheral circuit elements 260 and 360 may constitute a peripheral circuit that controls the operation of the semiconductor device. For example, each of the lower and upper peripheral circuit elements 260 and 360 may include a logic circuit 1130, a page buffer 1120, a decoder 1110, etc. of FIG. 22. The surface of the peripheral circuit substrates 200 and 300 in which the peripheral circuit elements 260 and 360 are placed may be referred to as a front side and/or a top surface of the peripheral circuit substrates 200 and 300. The surface of the peripheral circuit substrates 200 and 300 opposite to the front side of the peripheral circuit substrates 200 and 300 may be referred to as a backside and/or a bottom surface of the peripheral circuit substrates 200 and 300.

Each of the peripheral circuit elements 260 and 360 may include, for example, a transistor, but example embodiments are not limited thereto. For example, the peripheral circuit elements 260 and 360 may include various active elements such as a transistor, but various passive elements such as a capacitor, a resistor, an inductor, etc. According to some example embodiments, a first element separation film 210 that defines an active area of the lower peripheral circuit element 260 may be placed at the both sides of the lower peripheral circuit element 260. A second element separation film 310 that defines an active area of the upper peripheral circuit element 360 may be placed at the both sides of the upper peripheral circuit element 360. The first and second separation films 210 and 310 may be formed of an oxide film, a nitride film, and/or a combination thereof.

The peripheral circuit elements 260 and 360 and peripheral wiring structures 280 and 380 connected to the peripheral circuit elements 260 and 360 may be formed on each of the peripheral circuit substrates 200 and 300. The lower peripheral wiring structure 280 may be formed on the lower peripheral circuit element 260, for example, in the lower peripheral insulating film 240 formed at the front side of the lower peripheral circuit substrate 200. The lower peripheral wiring structure 280 may be electrically connected to the lower peripheral circuit element 260. In the similar manner, the upper peripheral wiring structure 380 may be formed on the upper peripheral circuit element 360, and placed in the upper peripheral insulating film 340 formed at the front side of the upper peripheral circuit substrate 300. The upper peripheral wiring structure 280 may be electrically connected to the upper peripheral circuit element 360. The number and arrangement of layers of the peripheral wiring structures 280 and 380 of FIG. 2 are merely exemplary, and example embodiments are not limited thereto.

According to some example embodiments, the upper peripheral circuit structure PERI2 and the cell structure CELL may be connected by bonding. The upper peripheral circuit structure PERI2 and the cell structure CELL may be in contact with each other through a first bonding metal 185 formed in the cell structure CELL and a second bonding metal 385 formed in the upper peripheral circuit structure PERI2. According to some example embodiments, the first bonding metal 185 and the second bonding metal 385 may include copper (Cu), but example embodiments are not limited thereto. The first bonding metal 185 and the second bonding metal 385 may be formed of various metals such as Aluminum (Al) or Tungsten (W). As the first bonding metal 185 and the second bonding metal 385 are bonded, the cell wiring structure 180 may be connected to the upper peripheral wiring structure 380. The bit line BL and/or each of the gate electrodes 120 may be electrically connected to the upper peripheral circuit element 360.

According to some example embodiments, the lower peripheral circuit structure PERI1 and the upper peripheral circuit structure PERI2 may be connected to each other by bonding. A bonding structure BA may be placed between the lower peripheral circuit structure PERI1 and the upper peripheral circuit structure PERI2. The bonding structure BA may include a lower bonding layer BN1 placed on the lower peripheral circuit structure PERI1 and an upper bonding layer BN2 placed on the lower bonding layer BN1.

According to some example embodiments, the lower bonding layer BN1 may include a lower bonding insulating film 410 and a plurality of lower pads 420 formed in the lower bonding insulating film 410, and the upper bonding layer BN2 may include an upper bonding insulating film 510 and a plurality of upper pads 520 formed in the upper bonding insulating film 510.

The lower bonding insulating film 410 and the upper bonding insulating film 510 may include, for example, at least one of silicon oxide (SiO), silicon nitride (SiN), silicon oxynitride (SiON), and a low-k material. A low-k material having a low dielectric constant may include, for example, Fluorinated TetraEthylOrthosilicate (FTEOS), Hydrogen Silsesquioxane (HSQ), Bis-benzocyclobutene (BCB), Tetramethyl Orthosilicate (TMOS), Octamethylcyclotetrasiloxane (OMCTS), Hexamethyldisiloxane (HMDS), Trimethylsilyl Borate (TMSB), DiAcetoxyDitertiaryButoSiloxane (DADBS), Trimethylsilyl Phosphate (TMSP), PolyTetraFluoroEthylene (PTFE), Tonen SilaZen (TOSZ), Fluoride Silicate Glass (FSG), polyimide nanofoams such as polypropylene oxide, Carbon Doped silicon Oxide (CDO), Organo Silicate Glass (OSG), SiLK, Amorphous Fluorinated Carbon, silica aerogels, silica xerogels, mesoporous silica and/or combinations thereof, but example embodiments are not limited thereto.

A plurality of lower pads 420 and a plurality of upper pads 520 may correspond to each other. The feature that the lower pad 420 corresponds to the upper pad 520 may indicate that the center axes of the lower pad 420 and the upper pad 520 may be placed to align with each other, but also indicate that the lower pad 420 and the upper pad 520 may be placed at specific locations according to a predetermined, or alternatively desired pattern. For example, each of the plurality of lower pads 420 and each of the plurality of upper pads 520 may be placed to have a different size and/or shape.

According to some example embodiments, the lower and upper pads 420 and 520 may include a conductive pad. The plurality of lower pads 420 and the plurality of upper pads 520 may contact each other, and the lower peripheral circuit structure PERI1 and the upper peripheral circuit structure PERI2 may be electrically connected to each other. According to some example embodiments, the lower and upper pads 420 and 520 may include an align key. The lower and upper pads 420 and 520 may be used to align and/or combine the lower peripheral circuit structure PERI1 and the upper peripheral circuit structure PERI2. The number and arrangement of layers of the lower and upper pads 420 and 520 of FIG. 2 are merely exemplary, and example embodiments are not limited thereto.

According to some example embodiments, a first thickness H1 of the lower peripheral circuit substrate 200 may be greater than a second thickness H2 of the upper peripheral circuit substrate 300. For example, when the lower peripheral circuit structure PERI1 and the upper peripheral circuit structure PERI2 are bonded, a portion of the upper peripheral circuit substrate 300 may be removed by a planarization process. Accordingly, in some example embodiments, a distance between the upper surface and the lower surface of the lower peripheral circuit substrate 200 (e.g., the first thickness H1) may be greater than a distance between the upper surface and the lower surface of the upper peripheral circuit substrate 300 (e.g., the second thickness H2).

The bonding structure BA may include a shielding element SE. For example, the shielding element SE may be formed in the lower bonding layer BN1, the upper bonding layer BN2, or in the lower bonding layer BN1 and the upper bonding layer BN2. The shielding element SE may be formed of a single element, or a plurality of separate elements. According to some example embodiments, the shielding element SE may overlap a first upper peripheral circuit element 362 among a plurality of upper peripheral circuit elements 360 in a vertical direction (e.g., the third direction D3). The lower peripheral wiring structure 280 may include a first lower wiring line 282 to which a predetermined, or alternatively desired range of voltage is applied. The predetermined, or alternatively desired range of voltage may range from 28V to 30V. However, example embodiments are not limited thereto. The shielding element SE may overlap a portion of a first lower wiring line 282 in the third direction D3. The shielding element SE may be interposed between the first upper peripheral circuit element 362 and the first lower wiring line 282 overlapping in the third direction D3. According to some example embodiments, even though a high-voltage (e.g., a voltage ranging from 28V to 30V) is applied to an adjacent wiring line (e.g., 282 of FIG. 2) in the lower peripheral circuit structure PERI1, the characteristic of the first upper peripheral circuit element 362 may be maintained because the shielding element SE blocks the influence of high voltage.

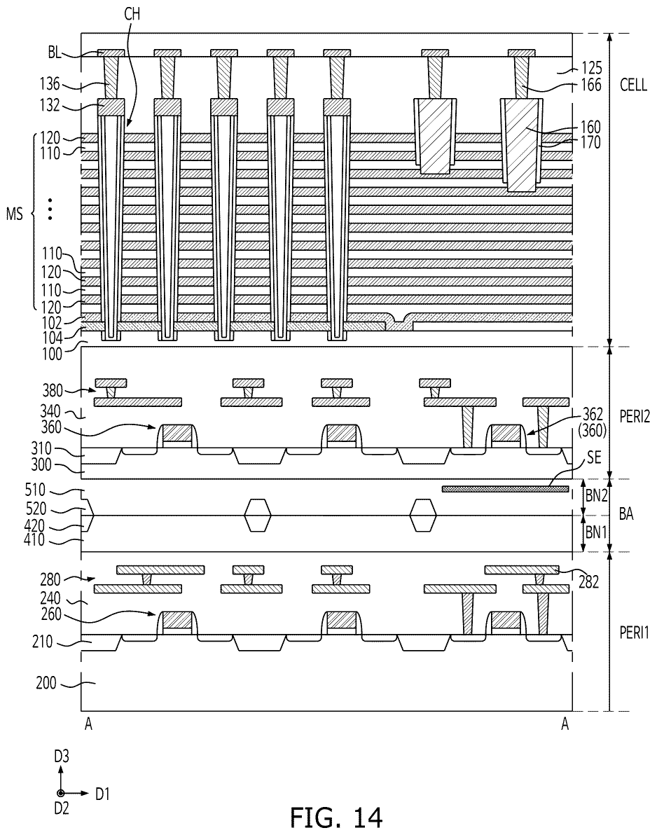

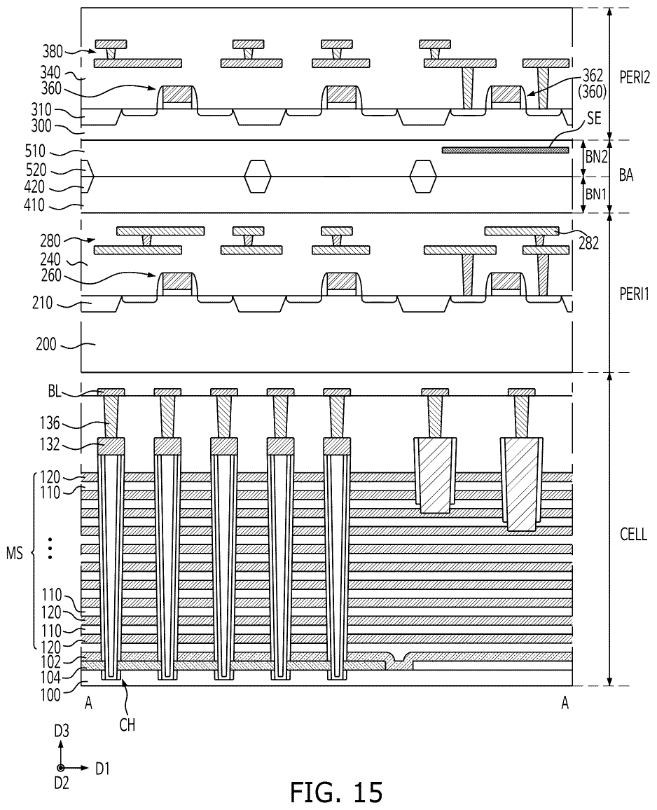

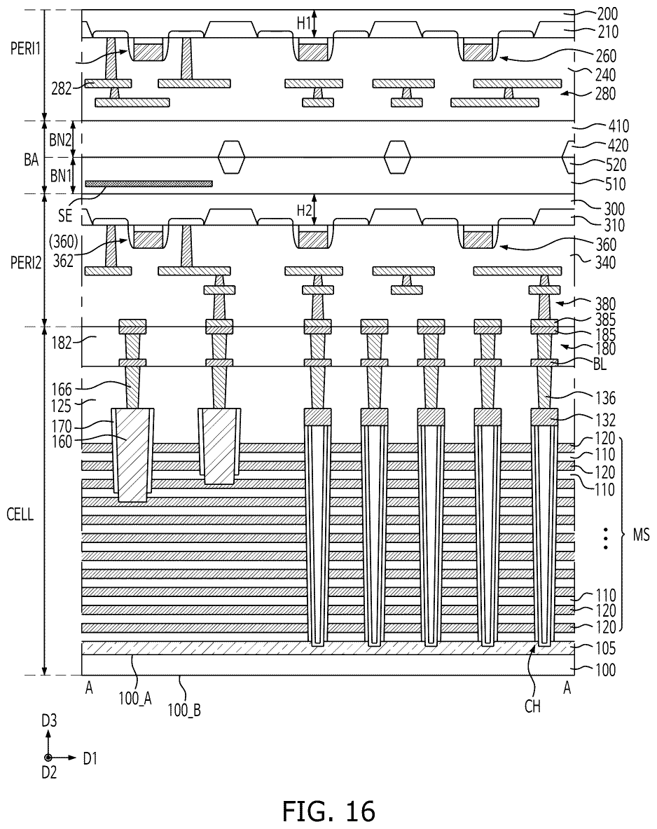

According to some example embodiments, the cell structure CELL may be stacked with the upper peripheral circuit structure PERI2 and the wiring structure. For example, the upper peripheral circuit structure PERI2 may be stacked on the wiring structure. The cell structure CELL may be stacked on the upper peripheral circuit structure PERI2. The wiring structure may include one or more wiring layers and insulating films. One or more wiring layers in the wiring structure may include a wiring line to which a predetermined, or alternatively desired range of voltage is applied. The wiring line, configured to receive the predetermined, or alternatively desired range of voltage, may overlap the first upper peripheral circuit element 362 among the plurality of upper peripheral circuit elements 360 in the vertical direction (e.g., the third direction D3). According to some example embodiments of the semiconductor device with reference to FIG. 2, FIG. 14, FIG. 15, and FIG. 16, the semiconductor device may include a wiring structure rather than the lower peripheral circuit structure PERI1.

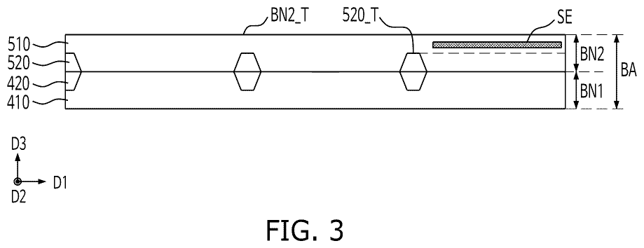

FIG. 3 to FIG. 8 are views illustrated to explain examples of shielding elements according to some example embodiments. The semiconductor device in FIG. 3 to FIG. 8 may be substantially the same as the semiconductor device described with reference to FIG. 1 and FIG. 2, except for the arrangement position of the shielding element. For ease of explanation, other configurations than those in FIG. 1 and FIG. 2 will be described in detail below according to some example embodiments.

It will be understood that elements and/or properties thereof may be received herein as being “the same” or “equal” as other elements, and it will be further understood that elements and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same.

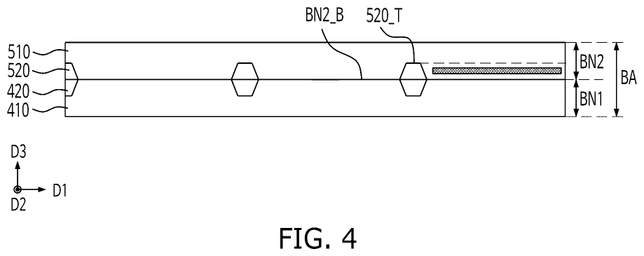

According to some example embodiments, the shielding element SE may be placed in the upper bonding layer BN2. The shielding element SE may be formed inside the upper bonding insulating film 510. For example, referring to FIG. 3, the shielding element SE may be interposed between an upper surface BN2_T of the upper bonding layer BN2 and an upper surface 520_T of the upper pad 520. The shielding element SE may be placed to be adjacent to the upper surface BN2_T of the upper bonding layer BN2. According to some example embodiments, e.g., referring to FIG. 4, the shielding element SE may be interposed between the upper surface 520_T of the upper pad 520 and a lower surface BN2_B of the upper bonding layer BN2. The shielding element SE may be placed to be adjacent to the lower surface BN2_B of the upper bonding layer BN2.

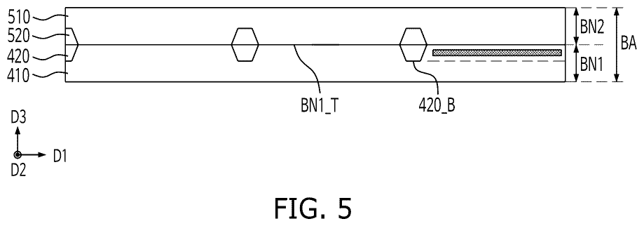

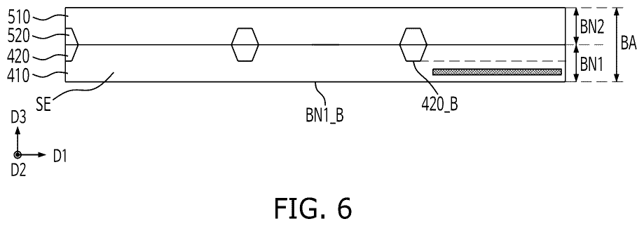

According to some example embodiments, the shielding element SE may be placed in the lower bonding layer BN1. The shielding element SE may be formed inside the lower bonding insulating film 410. For example, referring to FIG. 5, the shieling element SE may be interposed between an upper surface BN1_T of the lower bonding layer BN1 and a lower surface 420_B of the lower pad 420. The shielding element SE may be placed adjacent to the upper surface BN1_T of the lower bonding layer BN1. According to some example embodiments, referring to FIG. 6, the shielding element SE may be interposed between the lower surface 420_B of the lower pad 420 and the lower surface BN1_B of the lower bonding layer BN1. The shielding element SE may be placed adjacent to the lower surface BN1_B of the lower bonding layer BN1.

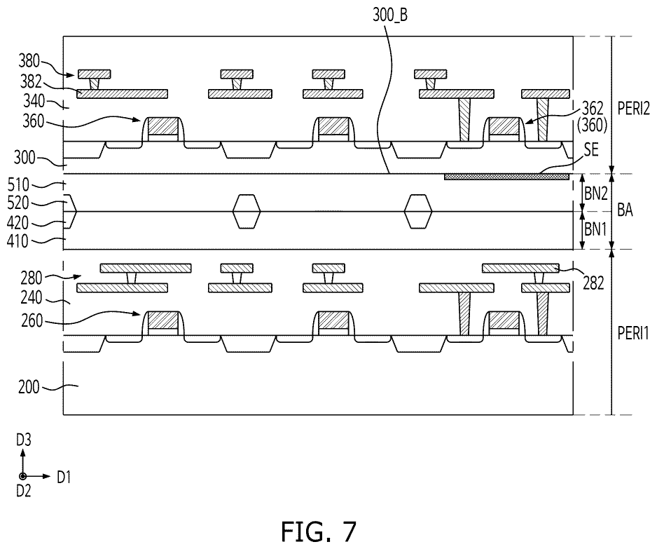

According to some example embodiments, the shielding element SE may be placed to contact a lower surface 300_B of the upper peripheral circuit substrate 300. Referring to FIG. 7, the upper surface of the shielding element SE may be disposed on the same surface as the lower surface 300_B of the upper peripheral circuit substrate 300. In some example embodiments, a voltage within a predetermined, or alternatively desired range may be applied to the shielding element SE, so that a substrate potential control of the upper peripheral circuit substrate 300 may be performed. For example, the voltage ranging from −5V to 5V may be applied to the shielding element SE. The shielding element SE may electrically contact the upper peripheral circuit substrate 300, and a voltage within a predetermined, or alternatively desired range may be applied to the upper peripheral circuit substrate 300. Accordingly, the substrate voltage, potentials of a p-type well, and an n-type well of the upper peripheral circuit substrate 300 may be maintained.

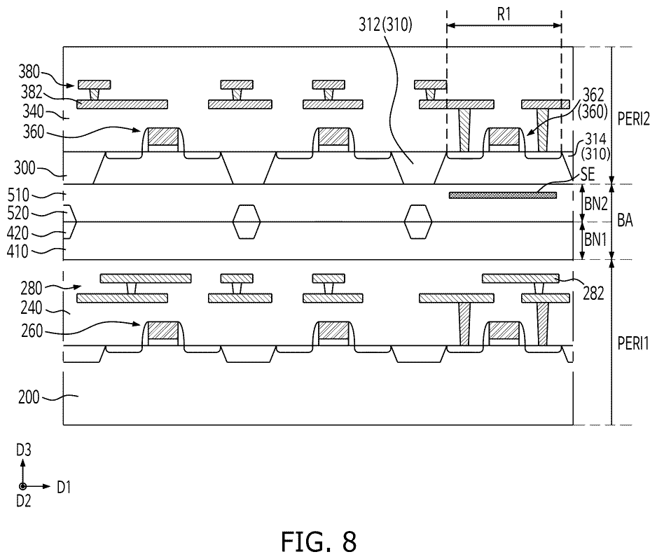

According to some example embodiments, the shielding element SE may be placed in an overlapping area in which the first upper peripheral circuit element 362 is arranged in the third direction D3. For example, referring to FIG. 8, a first element separation film 312 may be placed on one side surface of the first upper peripheral circuit element 362, and a second element separation film 314 may be placed on the other side surface of the first upper peripheral circuit element 362. The shielding element SE may be disposed at a peripheral circuit element region R1 defined by the first element separation film 312 and the second element separation film 314. The peripheral circuit element region R1 may be an area corresponding to a physical arrangement area of the first upper peripheral circuit element 362.

Some example embodiments for the arrangement positions of the shielding elements described with reference to FIG. 3 to FIG. 8 may be combined with each other. For example, the shielding element SE may include a plurality of shielding elements, and the shielding elements may be respectively arranged at the arrangement positions described with reference to FIG. 3 to FIG. 8. According to some example embodiments, the arrangement positions of the shielding elements described with reference to FIG. 3 to FIG. 7 and the arrangement positions of the shielding element described with reference to FIG. 8 may be combined with each other. For example, the shielding element SE may be placed in the peripheral circuit element region R1, and the upper surface of the shielding element SE may be disposed to have the same surface as the lower surface 300_B of the upper peripheral circuit substrate 300. According to some example embodiments, the shielding element SE may be placed at the arrangement position of the shielding element in the peripheral circuit element region R1 described with reference to FIG. 3 to FIG. 6.

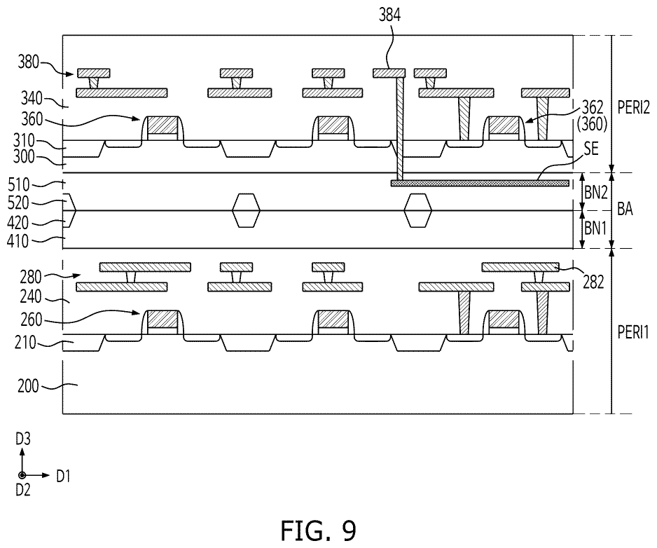

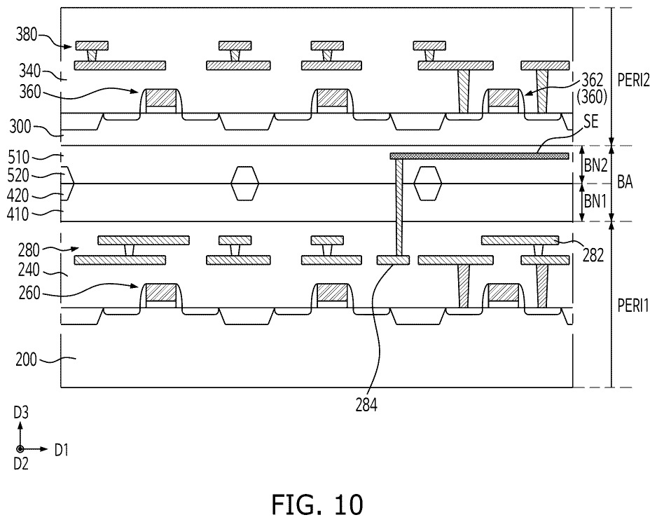

FIG. 9 and FIG. 10 are views illustrated to explain examples of shielding elements according to some example embodiments. The semiconductor device in FIG. 9 and FIG. 10 may be substantially the same as the semiconductor device described with reference to FIG. 1 to FIG. 8 except for the connection structure of the shielding element. For convenience of explanation, configurations other than those described with reference to FIG. 1 to FIG. 8 will be described in detail.

According to some example embodiments, the shielding element SE may be electrically connected to the peripheral wiring structures 280 and 380. For example, referring to FIG. 9, the shielding element SE may be electrically connected to an upper wiring line 384 among a plurality of upper wiring lines included in the upper peripheral wiring structure 380. According to some example embodiments, e.g., referring to FIG. 10, the shielding element SE may be electrically connected to a lower wiring line 284 among a plurality of lower wiring lines included in the lower peripheral wiring structure 280.

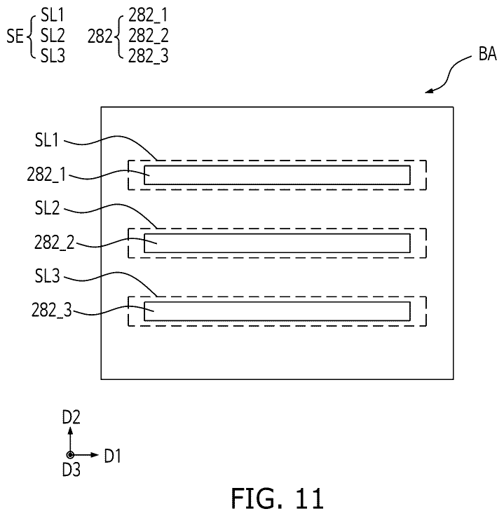

FIG. 11 to FIG. 13 are views illustrated to explain examples of shielding elements according to some example embodiments. The semiconductor device in FIG. 11 to FIG. 13 may be substantially the same as the semiconductor device described with reference to FIG. 1 to FIG. 10 except for the planar arrangement of the shielding element SE inside the bonding structure BN. For convenience of explanation, other configurations than those in FIG. 1 to FIG. 10 will be detailed.

According to some example embodiments, the shielding element SE may have a shape corresponding to the first lower wiring line 282 and may be arranged to overlap the first lower wiring line 282 in the third direction D3. The shielding element SE may include a plurality of shielding lines SL1, SL2 and SL3. In some example embodiments, the first lower wiring line 282 may include a plurality of sub-lower wiring lines 282_1, 282_2 and 282_3. In some example embodiments, each of the plurality of shielding lines SL may have a shape corresponding to each of the plurality of sub-lower wiring lines 282_1, 282_2 and 282_3. For example, referring to FIG. 11, a first shielding line SL1 may overlap a first sub-lower wiring line 282_1 in the third direction D3. A second shield line SL2 may overlap a second sub-lower wiring line 282_2 in the third direction D3. A third shield line SL3 may overlap a third sub-lower wiring line 282_3 in the third direction D3.

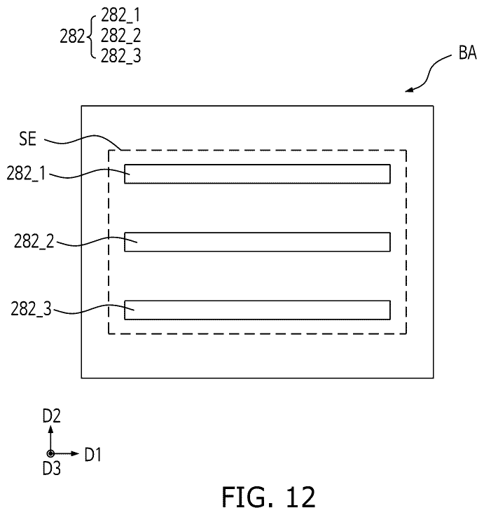

According to some example embodiments, the shielding element SE may include a shielding plate. In some example embodiments, the shielding plate may overlap the plurality of sub-lower wiring lines 282_1, 282_2 and 282_3 in the third direction D3. For example, referring to FIG. 12, the plurality of sub-lower wiring lines 282_1, 282_2 and 282_3 may be arranged in an area overlapping the shielding plate in the third direction D3.

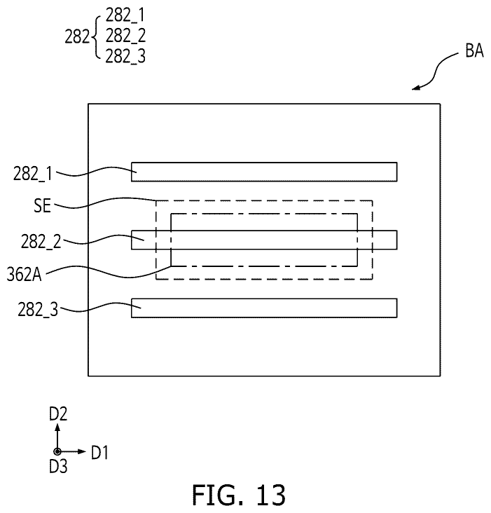

According to some example embodiments, the shielding element SE may be arranged to overlap a first upper peripheral circuit element area 362A in the third direction D3. The first upper peripheral circuit element area 362A may be a planar arrangement area occupied by the first upper peripheral circuit element 362 arranged in the upper peripheral circuit structure PERI2. In some example embodiments, the shielding element SE may overlap a portion of the plurality of sub-lower wiring lines 282_1, 282_2 and 282_3 in the third direction D3. For example, referring to FIG. 13, the shielding element SE may not overlap the first sub-lower wiring line 282_1 and the third sub-lower wiring line 282_3. The shielding element SE may overlap a portion of the second sub-lower wiring line 282_2 in the third direction D3. According to some example embodiments, e.g., illustrated in FIG. 13, a shielding element SE is arranged at a position corresponding to a first upper peripheral circuit element area 362A, but example embodiments are not limited to the example of a vertical arrangement between the shielding element SE and the plurality of sub-lower wiring lines 282_1, 282_2 and 282_3 illustrated in FIG. 13. For example, the shielding element SE may overlap the first upper peripheral circuit element area 362A in the third direction D3 and the plurality of sub-lower wiring lines 282_1, 282_2, and 282_3 in the third direction D3.

FIG. 14 is a view illustrated to explain a semiconductor device according to some example embodiments. FIG. 14 is a view corresponding to a cross-section of FIG. 1 taken along line A-A. For ease of explanation, other configurations than those in FIG. 1 to FIG. 13 will be described in detail.

Referring to FIG. 14, a semiconductor device according to some example embodiments may include a lower peripheral circuit structure PERI1, an upper peripheral circuit structure PERI2, and a cell structure CELL.

The upper peripheral circuit structure PERI2 may be placed on the lower peripheral circuit structure PERI1, and the cell structure CELL may be placed on the upper peripheral circuit structure PERI2. The description of the peripheral circuit structures PERI1 and PERI2 may be the same as those in FIG. 1 to FIG. 13.

The cell structure CELL may include a cell substrate 100, a mold structure MS, a channel structure CH, a bit line BL, a word line contact 160, and a contact spacer 170.

The cell substrate 100 may be disposed on the upper peripheral circuit structure PERI2. The cell substrate 100 may include a semiconductor substrate such as a silicon substrate, a germanium substrate, or a silicon-germanium substrate. Alternatively, the cell substrate 100 may include a silicon-on-insulator (SOI) substrate, a germanium-on-insulator (GOI) substrate, etc. According to some example embodiments, the cell substrate 100 may include impurities. For example, the cell substrate 100 may include n-type impurities (e.g., phosphorus (P), arsenic (As), etc.).

Source structures 102 and 104 may be formed on the cell substrate 100. The structures 102 and 104 may be interposed between the cell substrate 100 and the mold structure MS. For example, the source structures 102 and 104 may extend along the upper surface of the cell substrate 100. The source structures 102 and 104 may be formed to contact the semiconductor pattern of the channel structure CH. For example, a second source layer 104 of the source structures 102 and 104 may penetrate an information storage film and contact the semiconductor pattern. The source structures 102 and 104 may be provided to a common source line (e.g., CSL of FIG. 22) of the semiconductor device. The source structures 102 and 104 may include polysilicon or a metal doped with impurities, but example embodiments are not limited thereto.

According to some example embodiments, the channel structure CH may penetrate the source structures 102 and 104. For example, the lower portion of the channel structure CH may penetrate the source structures 102 and 104 to be placed inside the cell substrate 100.

According to some example embodiments, the source structures 102 and 104 may be formed in multiple layers. For example, the source structures 102 and 104 may include a first source layer 102 and a second source layer 104 sequentially stacked on the cell substrate 100. The first source layer 102 and the second source layer 104 each may include polysilicon doped with impurities or polysilicon not doped with impurities, but example embodiments are not limited thereto. The first source layer 102 may contact the semiconductor pattern to be provided to a common source line (e.g., CSL of FIG. 22) of the semiconductor device. The second source layer 104 may be used as a support layer to prevent the collapse of a mold stack (e.g., the mold structure MS) in the replacement process for forming the first source layer 102.

Although not shown, in some example embodiments, a base insulating film may be disposed between the cell substrate 100 and the source structures 102 and 104. The base insulating film may include, for example, at least one of silicon oxide, silicon nitride and silicon oxynitride, but example embodiments are not limited thereto.

FIG. 15 is a view illustrated to explain a semiconductor device according to some example embodiments. FIG. 15 is a view corresponding to a cross-section of FIG. 1 taken along line A-A. For ease of explanation, other configuration than those described in FIG. 1 to FIG. 14 will be described in detail.

Referring to FIG. 15, a semiconductor device according to some example embodiments may include a lower peripheral circuit structure PERI1, an upper peripheral circuit structure PERI2, and a cell structure CELL. The lower peripheral circuit structure PERI1 may be disposed on the cell structure CELL, and the upper peripheral circuit structure PERI2 may be disposed on the lower peripheral circuit structure PERI1.

According to some example embodiments, the description of the cell structure CELL may be the same as that described in FIG. 14. According to some example embodimets, the description of the peripheral circuit structures PERI1 and PERI2 may be the same as those described in FIG. 1 to FIG. 14.

FIG. 16 is a view illustrated to explain a semiconductor device according to some example embodiments. FIG. 16 is a view corresponding to a cross-section of FIG. 1 taken along line A-A. For ease of explanation, other configurations than those described in FIG. 1 to FIG. 15 will be described in detail.

Referring to FIG. 16, a semiconductor device according to some example embodiments may have the same shape as the semiconductor device described in FIG. 2 with the upper and lower portions upside down. For example, the upper peripheral circuit structure PERI2 may be placed on the lower peripheral circuit structure PERI1, and the semiconductor device in which the cell structure CELL is placed on the upper peripheral circuit structure PERI2 may be in an upside-down shape.

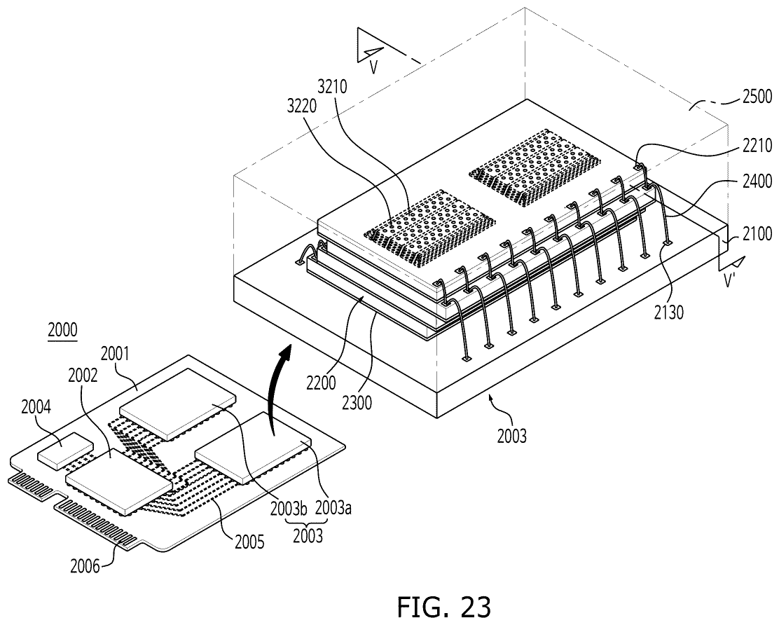

According to some example embodiments, a first thickness H1 of the lower peripheral circuit substrate 200 may be smaller than a second thickness H2 of the upper peripheral circuit substrate 300. A planarizing process for connecting an input and output pad (e.g., 2210 of FIG. 23) to the lower peripheral circuit substrate 200 of the lower peripheral circuit structure PERI1 may be performed, thereby removing a portion of the lower peripheral circuit substrate 200. Accordingly, a distance (e.g., the first thickness (H1)) between the upper surface and the lower surface of the lower peripheral circuit substrate 200 may be smaller than a distance (e.g., the second thickness (H2)) between the upper surface and the lower surface of the upper peripheral circuit substrate 300.

According to some example embodiments, the description on the elements of the cell structure CELL may be the same as those in FIG. 1 to FIG. 15. According to some example embodiments, the description of elements of the peripheral circuit structures PERI1 and PERI2 may be the same as those in FIG. 1 to FIG. 15.

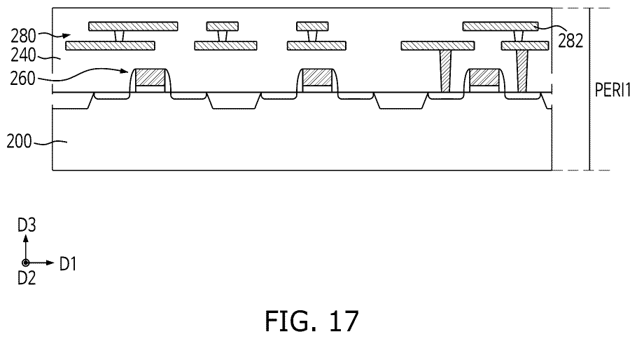

FIG. 17 to FIG. 21 are views illustrated to explain a manufacturing method of a semiconductor device according to some example embodiments.

Referring to FIG. 17, a lower peripheral circuit structure PERI1 may be formed. For example, a plurality of lower peripheral circuit elements 260 may be formed on a lower peripheral circuit substrate 200, and a lower peripheral insulating film 240 may be stacked on the lower peripheral circuit substrate 200. A lower peripheral wiring structure 280 may be formed in the lower peripheral insulating film 240.

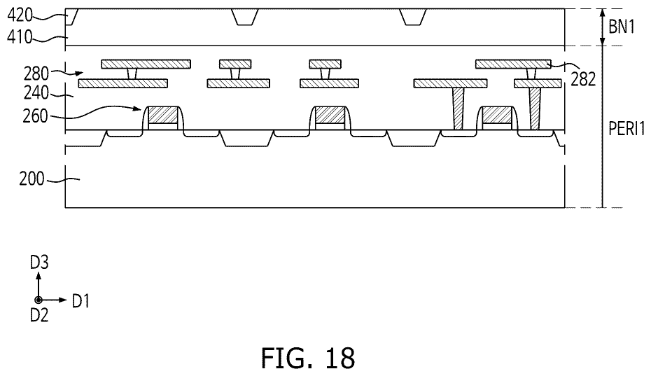

Referring to FIG. 18, a lower bonding layer BN1 may be formed on the lower peripheral circuit structure PERI1. For example, a lower bonding insulating film 410 may be formed on the lower peripheral insulating film 240, and a lower pad 420 may be formed inside the lower bonding insulating film 410.

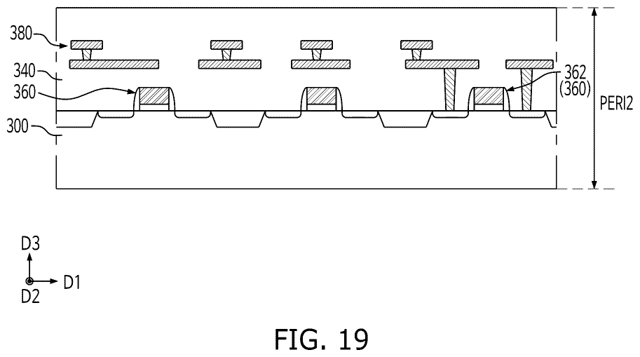

Referring to FIG. 19, the upper peripheral circuit structure PERI2 may be formed. For example, a plurality of upper peripheral circuit elements 360 may be formed on an upper peripheral circuit substrate 300, and an upper peripheral insulating film 340 may be stacked on the upper peripheral circuit substrate 300. A upper peripheral wiring structure 380 may be formed in the upper peripheral insulating film 340.

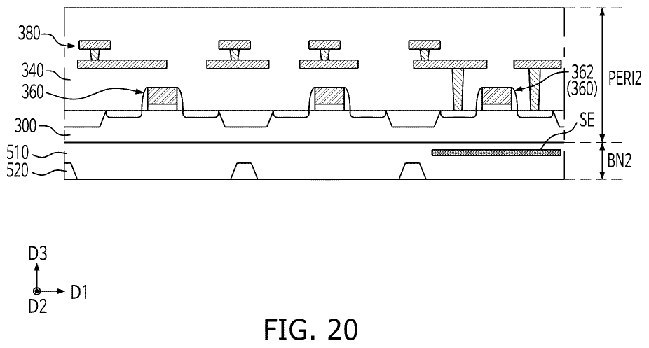

Referring to FIG. 20, an upper bonding layer BN2 may be formed on the upper peripheral circuit structure PERI2. For example, an upper bonding insulating film 510 may be formed on the upper peripheral circuit substrate 300, and an upper pad 520 may be formed inside the upper bonding insulating film 510. A shielding element SE may be formed inside the upper bonding insulating film 510. The shielding element SE may be formed to overlap an upper peripheral circuit element 362, which is placed at the position corresponding to a wiring line to which a high-voltage is applied in the lower peripheral circuit structure PERI1, in the third direction D3.

According to some example embodiments, a planarization process of the upper peripheral circuit substrate 300 may be performed before the upper bonding layer BN2 is formed. According to the planarization process of the lower surface (or a back side) of the upper peripheral circuit substrate 300, the thickness of the upper peripheral circuit substrate 300 after the upper bonding layer BN2 is formed may be smaller than the thickness of the upper peripheral circuit substrate 300 before the upper bonding layer BN2 is formed.

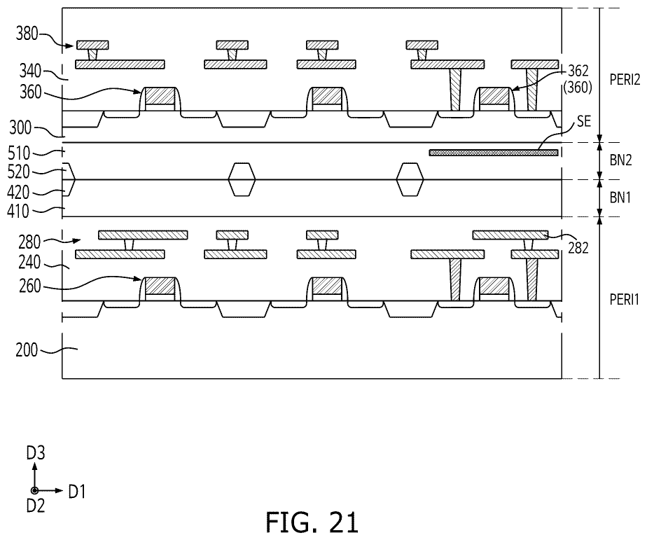

Referring to FIG. 21, the lower bonding layer BN1 and the upper bonding layer BN2 may be connected to each other by bonding. For example, the upper bonding insulating film 510 may be placed on the lower bonding insulating film 410. According to some example embodiments, a lower pad 420 and an upper pad 520 may combine or connect the lower bonding layer BN1 and the upper bonding layer BN2, or may be used to contact the lower bonding layer BN1 to the upper bonding layer BN2 by bonding.

A cell structure (e.g., CELL of FIG. 2) may be formed on the upper peripheral circuit structure PERI1. Therefore, according to some example embodiments, the semiconductor device described with reference to FIG. 1 to FIG. 14 may be provided. In some example embodiments, the cell structure may be formed under the lower peripheral circuit structure PERI2. Therefore, according to some example embodiments, the semiconductor device described in FIG. 15 may be provided.

FIG. 22 is an exemplary block view illustrated to explain an electronic system according to some example embodiments.

Referring to FIG. 22, an electronic system 1000 according to some example embodiments may include a semiconductor device 1100 and a controller 1200 electrically connected to the semiconductor device 1100 described with reference to FIG. 1 to FIG. 15. The electronic system 1000 may be a storage device including one or more semiconductor devices 1100 or an electronic device including a storage device. For example, the electronic system 1000 may be a solid-state drive (SSD) including one or more semiconductor devices 1100, a Universal Serial Bus (USB) device, a computing system, a medical device, and/or a communication device, but example embodiments are not limited thereto.

The semiconductor device 1100 may be, for example, a NAND flash memory device described above with reference to FIG. 1 to FIG. 15. The semiconductor device 1100 may include a first structure 1100F and a second structure 1100S on the first structure 1100F. The first structure 1100F may be a peripheral circuit structure including a decoder circuit 1110, a page buffer 1120, and a logic circuit 1130. The first structure 1100F may include a plurality of peripheral circuit structures (e.g., PERI1 and PERI2 of FIG. 2). For example, the first structure 1100F may include a plurality of peripheral circuit structures stacked by bonding. The second structure 1100S may be a memory cell structure including a bit line BL, a common source line CSL, word lines WL, first and second gate upper lines UL1 and UL2, first and second gate lower lines LL1 and LL2, and memory cell strings CSTR between the bit line BL and the common source line CSL.

In the second structure 1100S, each of the memory cell strings CSTR may include lower transistors LT1 and LT2 adjacent to the common source line CSL, upper transistors UT1 and UT2 adjacent to the bit line BL, and a plurality of memory cell transistors MCT disposed between the lower transistors LT1 and LT2 and the upper transistors UT1 and UT2, but example embodiments are not limited thereto. According to some example embodiments, the number of lower transistors LT1 and LT2 and the number of upper transistors UT1 and UT2 may vary depending on some example embodiments.

According to some example embodiments, the upper transistors UT1 and UT2 may include string select transistors, and the lower transistors LT1 and LT2 may include ground select transistors. The gate lower lines LL1 and LL2 may be gate electrodes of the lower transistors LT1 and LT2, respectively. The word lines WL may be gate electrodes of the memory cell transistors MCT, and the gate upper lines UL1 and UL2 may be gate electrodes of the upper transistors UT1 and UT2, respectively.

The common source line CSL, the first and second gate lower lines LL1 and LL2, the word lines WL, and the first and second gate upper lines UL1 and UL2 may be electrically connected to the decoder circuit 1110 through first connection wires 1115 extending from within the first structure 1100F to the second structure 1100S. The bit lines BL may be electrically connected to the page buffer 1120 through second connection wires 1125 extending from within the first structure 1100F to the second structure 1100S.

According to the first structure 1100F, the decoder circuit 1110 and the page buffer 1120 may execute a control operation for at least one select memory cell transistor among a plurality of memory cell transistors MCT. The decoder circuit 1110 and the page buffer 1120 may be controlled by the logic circuit 1130. The semiconductor device 1100 may communicate with a controller 1200 through an input and output pad 1101 electrically connected to the logic circuit 1130. The input and output pad 1101 may be electrically connected to the logic circuit 1130 through an input and output wiring line 1135 extending from within the first structure 1100F to the second structure 1100S.

The controller 1200 may include a processor 1210, a NAND controller 1220, and a host interface 1230. According to some example embodiments, the electronic system 1000 may include a plurality of semiconductor devices 1100, and in some example embodiments, the controller 1200 may control the plurality of semiconductor devices 1100.

The processor 1210 may control the overall operation of the electronic system 1000 including the controller 1200. The processor 1210 may operate according to a predetermined, or alternatively desired firmware, and control a NAND controller 1220 to access a semiconductor device 1100. The NAND controller 1220 may include a NAND interface (e.g., controller interface) 1221 that processes communication with the semiconductor device 1100. Through the NAND interface 1221, control commands for controlling the semiconductor device 1100, data to be written on the memory cell transistors MCT of the semiconductor device 1100, and data read from the memory cell transistors MCT of the semiconductor device 1100 may be transmitted or sent. A host interface 1230 may provide a communication function between the electronic system 1000 and an external host. When receiving a control command from an external host through the host interface 1230, the processor 1210 may control the semiconductor device 1100 in response to the control command. As described herein, any devices, electronic devices, modules, units, and/or portions thereof according to any of the example embodiments may include, may be included in, and/or may be implemented by one or more instances of processing circuitry such as hardware including logic circuits; a hardware/software combination such as a processor executing software; or a combination thereof. In some example embodiments, the processing circuitry may include a non-transitory computer readable storage device (e.g., a memory), for example a solid state drive (SSD), storing a program of instructions, and a processor (e.g., CPU) configured to execute the program of instructions to implement the functionality and/or methods performed by some or all of any devices, electronic devices, modules, units, and/or portions thereof according to any of the example embodiments.

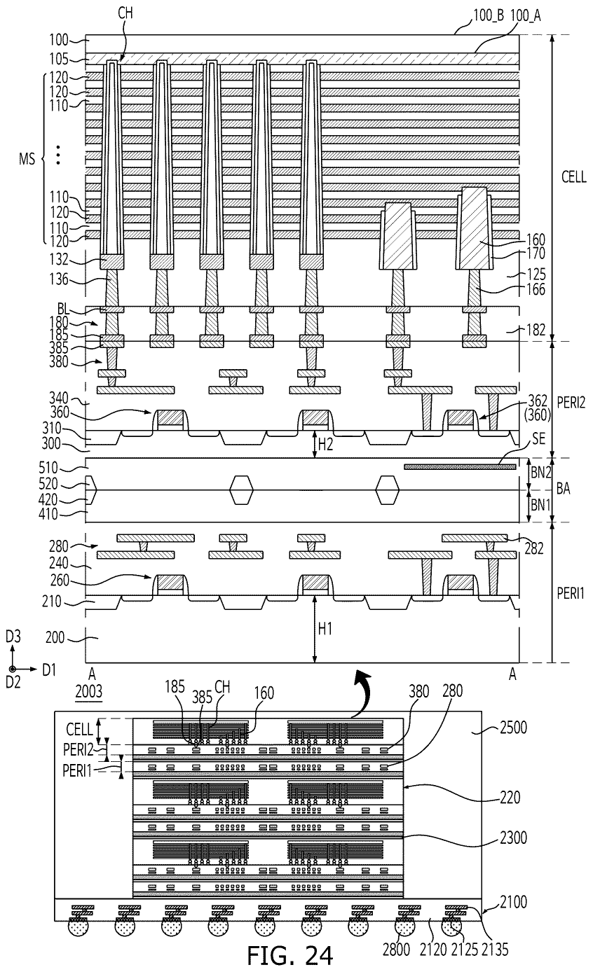

FIG. 23 is an exemplary perspective view illustrating an electronic system including a semiconductor device according to some example embodiments. FIG. 24 is a schematic cross-sectional view of FIG. 23 taken along line V-V according to some example embodiments.

Referring to FIG. 23, an electronic system 2000 according to some example embodiments may include a main substrate 2001, a controller 2002 mounted on the main substrate 2001, at least one semiconductor package 2003, and a DRAM 2004. The semiconductor package 2003 and the DRAM 2004 may be connected to the controller 2002 by wiring patterns 2005 formed on the main substrate 2001.

The main substrate 2001 may include a connector 2006 including a plurality of pins coupled with an external host. The number and arrangement of the plurality of pins in the connector 2006 may vary depending on a communication interface between the electronic system 2000 and the external host. According to some example embodiments, the electronic system 2000 may communicate with the external host according to any one of interfaces such as Universal Serial Bus (USB), Peripheral Component Interconnect Express (PCI-Express), Serial Advanced Technology Attachment (SATA), and/or M-Phy for Universal Flash Storage (UFS). According to some example embodiments, the electronic system 2000 may operate by a power supplied from the external host through the connector 2006. The electronic system 2000 may further include a Power Management Integrated Circuit (PMIC) that distributes the power supplied from the external host to the controller 2002 and the semiconductor package 2003.

The main controller 2002 may record data into the semiconductor package 2003, and read data from the semiconductor package 2003, and improve the operation speed of the electronic system 2000.

The DRAM 2004 may be a buffer memory for reducing the speed difference between the semiconductor package 2003, which is a data storage space, and an external host. The DRAM 2004 included in the electronic system 2000 may operate as a cache memory, and/or may provide a space for temporarily storing data in the control operation for the semiconductor package 2003. For example, when the DRAM 2004 is included in the electronic system 2000, the main controller 2002 may include a DRAM controller for controlling the DRAM 2004 in addition to a NAND controller for controlling the semiconductor package 2003.

The semiconductor package 2003 may include a first semiconductor package 2003a and a second semiconductor package 2003b spaced apart from each other. The first semiconductor package 2003a and the second semiconductor package 2003b each may be a semiconductor package including a plurality of semiconductor chips 2200. The first semiconductor package 2003a and a second semiconductor package 2003b each may include a package substrate 2100, semiconductor chips 2200 on the package substrate 2100, adhesive layers 2300 arranged at the lower surface of each of the semiconductor chips, connection structures 2400 electrically connecting the semiconductor chips 2200 and the package substrate 2100, and a molding layer 2500 that covers the semiconductor chips 2200 and the connection structure 2400 on the package substrate 2100.

The package substrate 2100 may be a printed circuit substrate including package upper pads 2130. Each of the semiconductor chips 2200 may include an input and output pad 2210. The input and output pad 2210 may correspond to the input and output pad 1101 of FIG. 22. Each of the semiconductor chips 2200 may include metal lines 3210 and channel structures 3220. Each of the semiconductor chips 2200 may include the semiconductor device described with reference to FIG. 1 to FIG. 15 according to some example embodiments.

According to some example embodiments, a connection structure 2400 may be a bonding wire that electrically connects the input and output pad 2210 and the package upper pads 2130. Therefore, according to some example embodiments, in each of a first semiconductor package 2003a and a second semiconductor package 2003b, the semiconductor chips 2200 may be electrically connected to each other by a bonding wire method, and electrically connected to the package upper pads 2130 of the package substrate 2100. According to some example embodiments, in each of a first semiconductor package 2003a and a second semiconductor package 2003b, the semiconductor chips 2200 may be electrically connected to each other by a connection structure that includes a Through Silicon Via (TSV) instead of the connection structure 2400 in the bonding wire method.

According to some example embodiments, the main controller 2002 and the semiconductor chips 2200 may be included in a single package. The main controller 2002 and the semiconductor chips 2200 may be mounted on a separate interposer substrate different from the main substrate 2001, and the main controller 2002 and the semiconductor chips 2200 may be connected to each other by a wiring line formed on the interposer substrate.

Referring to FIG. 23 and FIG. 24, according to some example embodiments, the package substrate 2100 may be a printed circuit substrate. The package substrate 2100 may include a package substrate body unit 2120, package upper pads 2130 disposed on the upper surface of the package substrate body unit 2120, lower pads 2125 arranged on the lower surface of the package substrate body unit 2120, or exposed through the lower surface, and inner wires 2135 electrically connecting the upper pads 2130 to the lower pads 2125 inside the package substrate body unit 2120. The upper pads 2130 may be electrically connected to the connection structures 2400. The lower pads 2125 may be connected to wire patterns 2005 of the main substrate 2001 of the electronic system 2000 through conductive connection units 2800 as shown in FIG. 23.

In an electronic system according to some example embodiments, each of the semiconductor chips 2200 may include the semiconductor device described with reference to FIG. 1 to FIG. 18. For example, at least part of the semiconductor chips 2200 may include an upper peripheral circuit structure PERI2 stacked on a lower peripheral circuit structure PERI1, and a cell structure CELL stacked on the upper peripheral circuit structure PERI2. In some example embodiments, at least part of the semiconductor chips 2200 may include the upper peripheral circuit structure PERI2 stacked on the lower peripheral circuit structure PERI1, and the cell structure CELL stacked under the upper peripheral circuit structure PERI2. For example, the peripheral circuit structures PERI1 and PERI2 may include the peripheral circuit substrates 200 and 300 and peripheral wiring structures 280 and 380 described with reference to FIG. 1 to FIG. 17. For example, the cell structure CELL may include the cell substrate 100, the mold structure MS, the channel structure CH, the bit line BL, the word line contact 160, and the contact spacer 170. The lower peripheral circuit structure PERI1 and the upper peripheral circuit structure PERI2 may be bonded to each other through the lower bonding layer BN1 and the upper bonding layer BN2. The peripheral circuit structure PERI1 and PERI2 and the cell structure CELL may be bonded to each other through the first bonding metal 185 and the second bonding metal 385.

Although some example embodiments of the present inventive concepts have been described with reference to the drawings, those skilled in the art will understand that some example embodiments of the present inventive concepts may be implemented in other various forms without departing from the technical spirits or essential features thereof. Accordingly, it should be understood that the example embodiments described above are exemplary in all respects but not restrictive.

What is claimed is:

1. A semiconductor device, comprising:
a lower peripheral circuit structure including a lower peripheral circuit substrate, a plurality of lower peripheral circuit elements on the lower peripheral circuit substrate, a lower peripheral insulating film stacked on the lower peripheral circuit substrate, and a lower peripheral wiring structure in the lower peripheral insulating film;
an upper peripheral circuit structure stacked on the lower peripheral circuit structure in a first direction, the upper peripheral circuit structure including an upper peripheral circuit substrate, a plurality of upper peripheral circuit elements on the upper peripheral circuit substrate, an upper peripheral insulating film staked on the upper peripheral circuit substrate, and an upper peripheral wiring structure arranged in the upper peripheral insulating film; and
a bonding structure including a shielding element, the bonding structure being between the lower peripheral circuit structure and the upper peripheral circuit structure,
the shielding element overlapping a first upper peripheral circuit element of the plurality of upper peripheral circuit elements in the first direction.

2. The semiconductor device as claimed in claim 1, wherein
the bonding structure includes a lower bonding layer on the lower peripheral circuit structure, and an upper bonding layer on the lower bonding layer,
the lower bonding layer includes a lower pad, and
the upper bonding layer includes an upper pad corresponding to the lower pad.

3. The semiconductor device as claimed in claim 2, wherein the shielding element is between an upper surface of the upper bonding layer and an upper surface of the upper pad.

4. The semiconductor device as claimed in claim 2, wherein the shielding element is between an upper surface of the upper pad and a lower surface of the upper bonding layer.

5. The semiconductor device as claimed in claim 2, wherein the shielding element is between an upper surface of the lower bonding layer and a lower surface of the lower pad.

6. The semiconductor device as claimed in claim 2, wherein the shielding element is between a lower surface of the lower pad and a lower surface of the lower bonding layer.

7. The semiconductor device as claimed in claim 1, wherein the shielding element contacts a lower surface of the upper peripheral circuit substrate.

8. The semiconductor device as claimed in claim 1, wherein the shielding element is in a peripheral circuit element area, which is defined by a first element separation film on one side surface of the first upper peripheral circuit element and a second element separation film on another side surface of the first upper peripheral circuit element.

9. The semiconductor device as claimed in claim 1, wherein a first thickness of the lower peripheral circuit substrate is greater than a second thickness of the upper peripheral circuit substrate.

10. The semiconductor device as claimed in claim 1, wherein
the lower peripheral wiring structure includes a lower wiring line configured to receive a voltage within a range, and
the shielding element overlaps at least a part of the lower wiring line in the first direction.

11. The semiconductor device as claimed in claim 10, wherein
the shielding element includes a shielding line, and
the shielding line has a shape corresponding to the lower wiring line.

12. The semiconductor device as claimed in claim 10, wherein
the lower wiring line includes a plurality of sub-lower wiring lines,
the shielding element includes a shielding plate, and
the shielding plate overlaps the plurality of sub-lower wiring lines in the first direction.

13. The semiconductor device as claimed in claim 1, wherein the shielding element is configured to receive a voltage.

14. The semiconductor device as claimed in claim 1, wherein the shielding element is electrically connected to one of a plurality of lower wiring lines included in the lower peripheral wiring structure.

15. The semiconductor device as claimed in claim 1, wherein the shielding element is electrically connected to one of a plurality of upper wiring lines included in the upper peripheral wiring structure.

16. A semiconductor device, comprising:
a lower peripheral circuit structure including lower peripheral circuit substrate, a plurality of lower peripheral circuit elements on the lower peripheral circuit substrate, a lower peripheral insulating film on the lower peripheral circuit substrate, and a lower peripheral wiring structure in the lower peripheral insulting film;
an upper peripheral circuit structure stacked on the lower peripheral circuit structure in a first direction, the upper peripheral circuit structure including an upper peripheral circuit substrate, a plurality of upper peripheral circuit elements on the upper peripheral circuit substrate, an upper peripheral insulating film stacked on the upper peripheral circuit substrate, and an upper peripheral wiring structure in the upper peripheral insulting film;
a bonding structure including a shielding element, the bonding structure being between the lower peripheral circuit structure and the upper peripheral circuit structure; and
a cell structure stacked on the lower peripheral circuit structure or the upper peripheral circuit structure in the first direction, the cell structure including,
a cell substrate including a cell array region and an extension region;
a mold structure including a plurality of mold insulating layers and a plurality of gate electrodes alternately stacked on the cell substrate in the first direction;
a channel structure on the cell array region, penetrating the mold structure, and extending in the first direction; and
a word line contact on the extension region, penetrating a portion of the mold structure, and extending in the first direction, and
the shielding element overlapping a first upper peripheral circuit element of the plurality of upper peripheral circuit elements in the first direction.

17. The semiconductor device as claimed in claim 16, wherein
the lower peripheral wiring structure includes a lower wiring line configured to receive a voltage within a range, and
the shielding element overlaps at least a part of the lower wiring line in the first direction.

18. The semiconductor device as claimed in claim 16, wherein the word line contact penetrates one or more gate electrodes of the plurality of gate electrodes.

19. The semiconductor device as claimed in claim 16, further comprising:
a bit line contacting the channel structure, and
a cell wiring structure bonded between the bit line and the upper peripheral circuit structure and between the word line contact and the upper peripheral circuit structure.

20. An electronic system, comprising:
a main substrate;
a semiconductor device stacked on the main substrate; and
a controller electrically connected to the semiconductor device on the main substrate, the semiconductor device including,
a lower peripheral circuit structure including a lower peripheral circuit substrate, a plurality of lower peripheral circuit elements on the lower peripheral circuit substrate, a lower peripheral insulating film stacked on the lower peripheral circuit substrate, and a lower peripheral wiring structure in the lower peripheral insulating film;
an upper peripheral circuit structure stacked on the lower peripheral circuit structure in a first direction, and including an upper peripheral circuit substrate, a plurality of upper peripheral circuit elements on the upper peripheral circuit substrate, an upper peripheral insulating film stacked on the upper peripheral circuit substrate, and the upper peripheral wiring structure in the upper peripheral insulating film;
a bonding structure including a shielding element, the bonding structure being between the lower peripheral circuit structure and the upper peripheral circuit structure, the shielding element overlapping a first upper peripheral circuit element of the plurality of upper peripheral circuit elements in the first direction; and
a cell structure, the cell structure including,
a cell substrate including a cell array region and an extension region;
a mold structure including a plurality of mold insulating layers and a plurality of gate electrodes alternately stacked on the cell substrate in the first direction;
a channel structure on the cell array region, penetrating the mold structure, and extending in the first direction; and
a word line contact on the extension region, penetrating a portion of the mold structure, and extending in the first direction.
